(19) United States
(12) Patent Application Publication
(10) Pub. No.: US 2003/0187967 A1
(43) Pub. Date: Oct. 2, 2003

(54) Method and apparatus to estimate downtime and cost of downtime in an information technology infrastructure

(75) Inventors: John B. Walsh, Galway (IE); Alan Rockall, Galway (IE); Alexander Sudarsky, Galway (IE)

Correspondence Address: CONLEY ROSE, P.C., P. O. BOX 3267, HOUSTON, TX, 77253-3267, US

(73) Assignee: Compaq Information, Houston, TX

(21) Appl. No.: 10/109,277

(22) Filed: Mar. 28, 2002

(51) Int. Cl. G06F 9/00; G06F 15/173; H03K 19/003; H05K 10/00; H02H 3/05; H04B 1/74

(52) U.S. Cl. 709/223; 714/2

(57) ABSTRACT

An availability analysis software tool for estimating the downtime and cost of downtime in an information technology network. The tool can create a computer element model of software and hardware components in the network. The elements are combinable into logical group models and element and group models are further combinable into a model tree to simulate the network. Each element is assigned a workload and the sum of element workloads determine group and model workloads. Simulated element failures reduce workload in the group and model tree. Cost per unit workload lost during an element failure are assignable, wherein the estimated cost of downtime caused by element failures is determined by multiplying the amount of workload that is lost from the simulated element failures by the cost per unit workload.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

1. Field of the Invention

The present invention generally relates to computer network infrastructures. More specifically, the present invention relates to the partial or total system downtime that arises when components within a computer network infrastructure fail. More specifically yet, the present invention relates to a computer software package for modeling a computer network infrastructure and estimating costs associated with downtime that results from the failure of components within a computer network infrastructure.

2. Background of the Invention

As computer systems become more powerful and data communication protocols permit larger data transfer rates, computer networks have accordingly become larger and more complex. With this increase in size and complexity comes the ability to create very powerful computer networks. Furthermore, the ease with which digital information can be transmitted, stored, and processed in a computer network means that businesses have come to rely heavily on computer network and information technology (IT) infrastructures. The planning and development of IT infrastructures is critical and IT professionals typically go to great lengths to plan and create networks that can efficiently handle business workloads. Consequently, IT professionals currently play a very important part in a company's business plan because the IT infrastructure is a key element in a company's day to day business.

One important factor that must be considered in developing an IT infrastructure is the negative impact caused by the failure of components in the IT infrastructure. Depending on how the IT network is configured, a component failure may have little impact on the network or it may cause a substantial failure resulting in unwanted downtime. In developing an infrastructure that is robust enough to handle component failures, there are typically several competing interests, including redundancy and cost. Redundancy may be built into the system to isolate component failures, such that when a component fails, the IT network automatically switches to a backup component to continue operation. However, complete system redundancy is generally unnecessary, excessive, as well as cost prohibitive. Therefore, a key to optimizing a robust IT infrastructure is to strike a fine balance between minimizing downtime caused by component failures and eliminating the cost of creating an overly redundant system.

Unfortunately, finding this optimum balance between competing interests can be a difficult task involving iterative analyses. An analysis to determine the optimum size and configuration of an IT infrastructure involves considerations such as hardware costs, time needed to recover the network or to repair failures, and cost of downtime. Additional information, such as time-dependent workload expectations or demands, hardware reliability, and business mission information are also needed to facilitate the design process. Gathering all this information and applying it to various IT infrastructure configurations easily becomes a nontrivial undertaking.

To help IT professionals perform these tasks, Compaq Computer Corporation has developed an “Availability Analysis Tool” (“AVANTO”) to model the uptime availability of network configurations. This tool allows IT professionals to plan and design systems that meet individualized business requirements. Specifically, the software tool allows IT professionals to create detailed computer models that represent current and/or proposed IT infrastructures. The software tool uses information on hardware, physical networks, physical environment, and management goals to create realistic models of actual networks. The software further permits the use of historical data including repair and recovery times and financial information to analyze the models and generate information on expected availability and downtime costs.

The AVANTO software tool uses hardware elements and groups as the basic building blocks of a network model. Elements represent individual hardware components in a network and groups are made up of multiple elements. Elements are arranged in serial structures to accurately reflect the layout of an actual IT infrastructure. The software tool also includes provisions for countermeasure elements, which are redundant elements that work to negate downtime or element failure costs. The software tool simulates component or model element failures to determine how the failures affect overall business missions.

Business missions may also be entered into the software tool in the form of a weekly calendar with two-hour workload segments that are assigned an impact value ranging from 0 to 100%. Thus, if network operation is most critical between the hours of 0600 and 1200 hours, Monday through Friday, the 2-hour segments within this critical window may be assigned an impact value closer to 100% while other segments may be assigned a lower impact value. Element failures may then be mapped into this grid and a cost calculated based on the business impact.

The usefulness of the AVANTO software tool lies in its ability to successfully model real-world networks and apply different scenarios before committing to any hardware purchases or reconfiguration. However, the existing software is somewhat limited in its ability to model all details of an IT infrastructure. Software and operating system failures are not accounted for and business missions are static from week to week. Furthermore, there is no provision for logical links between elements to permit accurate modeling of real-world component dependence. Also, there is no provision for elements operating together in a parallel fashion for redundancy or work co-operation.

Thus, despite the effectiveness of the existing AVANTO software tool, it would be desirable to build upon the existing functionality of the software so as to more accurately simulate IT infrastructures. Such a system would advantageously permit simulation of software and operating system failures as well as assigning workload values to individual elements to so as to identify contributions to the overall business mission. Furthermore, it would be desirable that the system would allow simulation of elements in parallel structures to reflect real world configurations. Other additional features may also be incorporated into the existing modeling tool to create a more accurate IT infrastructure modeling tool.

### BRIEF SUMMARY OF THE INVENTION

The problems noted above are solved in large part by an information technology (IT) network availability analysis tool. The tool is implemented as a software program that allows users to create a model of existing or proposed networks and simulates failures in the network. The software tool further analyzes these failures to determine the impact of these failures and assign a cost based on the simulated failures. The software tool is capable of generating a variety of reports that can be shown to a customer to aid in understanding design and implementation tradeoffs.

The tool estimates downtime and the cost of downtime in an IT network by creating a computer model of individual components in the information technology network and assigning a numerical workload to each component in the network. After simulating component failures in the computer model, the tool calculates the element downtime and the amount of workload that is lost. By assigning a cost per unit workload lost during a component failure, the estimated cost of downtime caused by component failures can be determined by multiplying the amount of workload that is lost from the simulated component failures by the cost per unit workload. The tool also estimates the amount of downtime for each component within the IT network.

A key step in accurately modeling the IT network is identifying functionally separable components in the network, including both software and hardware components. The tool allows users to create an element model for each component and to combine these element models into logical group models to simulate real-world configurations. Furthermore, a hierarchical model tree of both element and group models can be created to simulate the entire IT network.

Each element model is assigned a numerical workload, expressed in workload units. Elements are combinable within the group models in a serial or parallel manner. When element models are combined in a serial manner in a group model, the failure of any element model in the group model generally causes the group model to fail. By comparison, when element models are combined in a parallel manner in a group model, the sum of the workloads assigned to the individual element models determine the overall workload for the group model. Thus, if the group models are assigned a minimum workload, failures of element models within the group may cause the total workload for the group to equal or fall below the minimum workload thereby producing a group failure.

The network availability analysis software tool further comprises a business mission editor for creating variable business missions, each mission representing a grouping of adjacent time slots that are each assigned an expected network workload and network downtime cost. The tool includes a user interface for creating a sequence of the variable business missions. A failure simulator in the software generates failure points and repair times for the models based on historical reliability and repair or recovery trends exhibited by the network components and available remedial service coverage (or Software Support) in place at the time of the failure to effect a repair. These failure points and repair times are mapped against the sequence of business missions to determine which variable business mission is impacted by the failure point. The failure points and repair times are compared to the expected network workload and network downtime cost assigned to the time slot during which the failure occurs to calculate a downtime cost associated with each failure.

The network availability analysis software tool includes a user interface that allows a software user to enter a maximum expected network workload and network downtime cost. The business mission editor allows a software user to enter an expected network workload and a network downtime cost to each time slot as a percentage of the maximum expected workload and maximum network downtime cost. In the preferred embodiment, the variable business missions are one week long and the time slots are two hours long.

Failure points are assigned to elements using a simulated value based on a mean time between failure (MTBF) value for the element. Similarly, repair times are assigned based on a simulated value using a mean time to repair (MTTR) value for the element and availability of remedial service coverage. Once determined, the cost of the element failure is estimated by placing the future failure point in the appropriate time slot in the business mission. If the workload lost by the failure of the element impacts the expected network workload for that time slot, failure cost is determined from the network downtime cost for that time slot and the expected repair time for the element.

If the element is a software element, the future failure time may be adjusted based on user-definable software stability factors. The preferred software stability factors include: a proactive management factor, a patch management factor, a software maturity factor, a software stability factor, and a support training factor. Each of the software stability factors are adjustable to delay a future failure time if existing business practices represented by the factors lead to a more stable software application. In contrast, each of the software stability factors are adjustable to accelerate a future failure time if existing business practices represented by the factors lead to a less stable software application.

Similarly, the expected repair time can also be adjusted based on user-definable repair adjustment factors and period of available remedial service coverage. The preferred repair adjustment factors comprise: whether a software auto-restart function is enabled, the percentage of time a restart initiated by an enabled auto restart function fixes a software failure, the percentage of time software failures are categorized as severe/catastrophic, the percentage of time software failures are categorized as repairable, the percentage of time a manual service intervention fixes a software failure, and an estimated manual software restart time. If the software auto-restart function is enabled and a simulated failure is repaired by a restart initiated by the enabled auto restart function, the expected repair time is the reboot time. However, if a simulated failure is not repaired by a restart initiated by the enabled auto restart function, the expected repair time is increased to account for a more extensive repair effort.

If the simulated failure is categorized as severe or catastrophic, the expected repair time is increased by adding an extensive repair and recovery time based on a user defined value which adjusts the MTTR. If the simulated failure is categorized as repairable by a manual service intervention, the expected repair time is the estimated manual software restart time plus the remedial service time (which is governed by the service coverage details and when the failure occurred) plus the adjusted MTTR. Lastly, if the simulated failure is categorized as repairable, but not by a manual service intervention, the expected repair time is the estimated manual software restart time plus the remedial service time.

The preferred embodiment also implements reference elements and reference groups within a model. The preferred embodiment is configured to create correlated references between model members and referenced elements and groups that permit sharing of the characteristics of the same model member in the simulated network. The referenced element or group may be referred to as a master element or master group, whereas the reference element or reference group may be called the slave element or slave group. The failure simulator generates failure points and repair times for the master elements and master groups, but not for the slave elements or slave groups. Failure points and repair times generated for the master element and group are imparted onto the slave reference or slave group respectively. In addition to the failure points and repair times, the failure simulator further generates recovery times for the models based on an expected time needed to return to pre-failure operating capacity following a failure and repair. In general, recovery times for correlated slave reference elements and master elements are the same, but recovery times for correlated slave reference groups and referenced groups may be different.

User-definable workload factors may be applied to the model to increase or decrease the workload loss encountered by the group or model tree during a simulated element failure. An element failure workload factor increases or decreases the workload loss encountered by the group or model tree during the time a simulated element fails, but before the element is repaired. An element recovery workload factor increases or decreases the workload loss encountered by the group or model tree during the time after which a simulated element failure is repaired, but before the element has recovered. Lastly, a group recovery workload factor can be applied that increases or decreases the workload loss encountered by the group or model tree during the time after which a simulated element has recovered from a failure, but before the group in which the failed element resides has recovered.

### BRIEF DESCRIPTION OF THE DRAWINGS

For a detailed description of the preferred embodiments of the invention, reference will now be made to the accompanying drawings in which:

FIG. 1 shows a representative information technology (IT) network infrastructure that may be modeled and analyzed by the preferred embodiment;

FIG. 2 shows a representative tree structure model of a business mission comprising the basic group and element components of the preferred embodiment;

FIG. 3 shows a simple component model representing a serial and parallel component arrangement as permitted by the preferred embodiment;

FIG. 4 shows two representative timelines depicting the failure, recovery, and downtime effects of a component failure within the preferred embodiment;

FIG. 5 shows an example distribution of MTBF used to assign failure points in the preferred embodiment;

FIG. 6 shows an example distribution of MTTR used to assign recovery times in the preferred embodiment;

FIG. 7 shows a representative implementation of a parallel group of elements, each of which are assigned a workload contribution to the entire group in accordance with the preferred embodiment;

FIG. 8 shows a timeline depicting a hypothetical mission impact caused by failures of elements in the parallel group of FIG. 7;

FIG. 9 shows a representative implementation of a serial group of elements, each of which are assigned a workload contribution to the entire group in accordance with the preferred embodiment;

FIG. 10 shows a timeline depicting a hypothetical mission impact caused by failures of elements in the serial group of FIG. 9;

FIG. 11 shows a representative implementation of a parallel group of elements with failure workload factor and recovery workload factors assigned to the elements and group in accordance with the preferred embodiment;

FIG. 12 shows a timeline depicting a hypothetical mission impact caused by failures of elements in the parallel group of FIG. 11;

FIG. 13 shows a representative tree structure model of a business mission including workload transition graphs for each branch of the tree;

FIG. 14 shows a simple diagram of a shared component to which the concept of reference elements in accordance with the preferred embodiment is applicable;

FIG. 15 shows a representative tree structure model of a business mission indicating how workload transition graphs are shared with a reference component;

FIG. 16 shows a representative tree structure model of a business mission comprising a reference group and reference element components in accordance with the preferred embodiment;

FIG. 17 shows a user interface for defining business models in accordance with the preferred embodiment;

FIG. 18 shows a user interface for editing weekly business missions in accordance with the preferred embodiment;

FIG. 19 shows a software factor matrix used in the preferred embodiment to adjust software failure times in the preferred embodiment;

FIG. 20 shows a decision tree used in conjunction with user defined parameters by the preferred embodiment to calculate recovery and/or repair times for software failures; and

FIG. 21 shows a table listing the adjustment factors used in the preferred embodiment to calculate recovery and/or repair times for software failures.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”.

In addition, the following terms are used in determining the potential impact caused by component failures:

MTBC—Mean Time Between/Before Crash—Generally applicable to software failures, this term defines the amount of software uptime between crashes.

MTTR—Mean Time To Repair—Applicable to hardware and software failures, this term defines the amount of time required to repair a failure once the failure is detected.

MTTRec—Mean Time To Recover—This term defines the amount of time that elapses between a repair and the point at which operation returns to pre-failure workload.

MTBF—Mean Time Between Failure—Analogous to MTBC, this term defines the amount of hardware uptime between subsequent failures.

### DETAILED DESCRIPTION OF THE PREFERRED EMBODIMENTS

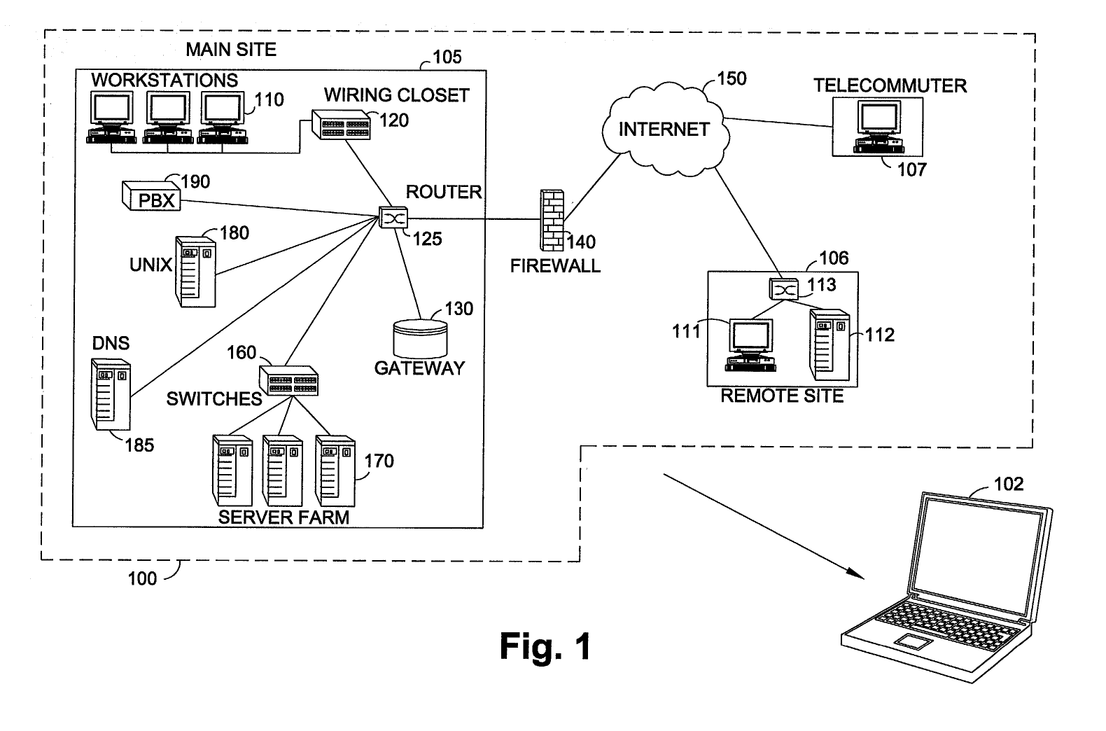

Turning now to the figures, FIG. 1 shows an example network infrastructure 100 that may be modeled and analyzed using the preferred availability analysis tool. The availability analysis tool is preferably embodied as a software program executable by a computer system. The preferred embodiment therefore seeks to capture the functionality of a real network into a computerized model. Ideally, the availability analysis tool is loaded onto a portable computer system 102 that can be taken to a customer site so that the software user can model a network while examining an existing network. In addition, this portable solution may advantageously allow the software user to interact with a customer to apply and determine the impact of any proposed changes to a model. Once a network is modeled, the preferred embodiment is capable of determining the impact, in downtime costs, of component failures within an IT network infrastructure and also to determine individual element and group downtimes. The software tool preferably simulates component failures in the network based on historical reliability data and available remedial service and calculates recovery times and downtime costs based on the time required to fully recover from a failure. This analysis is heavily dependent upon user inputs. Thus, given the interactive nature of the preferred availability analysis software tool, the usefulness of the software is enhanced by running the software on a portable computer to facilitate customer interaction. It should be noted however, that the software tool is equally capable of executing on a desktop or server computer (not shown).

The representative infrastructure 100 shown in FIG. 1 includes a main networking site 105 and also includes provisions for remote networking from a remote site 106 and a telecommuter site 107 (e.g., from an employee's home). In any representative enterprise network, there may be several hierarchical levels, in which components may reside. These levels are commonly known to those skilled in the art as the access or workgroup level, the distribution or policy level, and the core or backbone level. The boundaries between these levels are not necessarily clearly defined, but components within these levels certainly perform different functions. FIG. 1 does not include any specific demarcation of these various levels, but a cursory description of these levels in the context of the representative network of FIG. 1 is provided herein. It should also be noted that the hierarchical levels may also be described using numerical values (i.e., levels 1, 2, or 3).

The workgroup or access level is used to connect to users. Thus, in the example network shown in FIG. 1, workstations 110 and perhaps local area network (LAN) switches located in a wiring closet 120 may exist in this layer of the network. The distribution or policy level performs complex, CPU-intensive calculations such as filtering, inter-LAN routing, and broadcast and multicast protocol tasks. In general, policy implementation in large networks should be done closer to the workgroup level in order to avoid performance degradations which impact the entire network. The underlying theory is that the core should remain free of costly packet manipulation, and instead, should mainly be concerned with high speed transmission and switching. Devices commonly found in the backbone and policy layers include asynchronous transfer mode (ATM) switches, high-speed routers, and LAN switches (not specifically shown).

In the network shown in FIG. 1, the network router 125, gateway 130, and firewall 140 may reside in the core layer and provide access to external networks or the internet 150. By comparison, the switch bank 160 and the dependent server farm 170 may reside in the policy layer. The servers 170 may be NT or XP servers configured to execute and store applications and data for workstations 110. Additional components that may be included in the exemplary IT network 100 include a UNIX server 180 to handle non-Windows applications, a domain name system (DNS) server 185 to direct internet traffic, and a private branch exchange (PBX) network 190 to handle audio and video teleconferencing traffic.

The exemplary network 100 of FIG. 1 includes provisions for remote networking via a remote site 106 and a telecommuter site 107. A remote site 106 may include workstations 111, servers 112, routers 113, or other components as needed to sustain the workload seen by the remote site. Regardless of the configuration, the remote site 106 most likely resides beyond the main site firewall 140 for security reasons. Access to the main site network 105 is likely provided through a secured high-speed connection via the internet 150. Similarly, a telecommuter 107 may access the internal network 105 using an appropriate secured dial-up, ISDN, or frame relay connection.

It should be noted that the IT infrastructure 100 shown in FIG. 1 is offered by way of example and not by way of limitation. The infrastructure 100 shown is offered to portray some of the general complexities involved in building an efficient network. Those skilled in the art will certainly understand that other components may be included and such components may be coupled in a wide variety of configurations. In general, however, the exemplary IT infrastructure 100 shown in FIG. 1 exhibits characteristics that may be modeled using the preferred availability analysis tool. For example, the workstations 110 are deployed in a parallel fashion, whereas switches in wiring closet 120 are located serially between the workstations 110 and router 125. Another characteristic of the exemplary IT infrastructure is the shared nature of certain components. For instance, router 125 is coupled to multiple devices, including servers 180, 185 and switches 120, 160. Thus, it should be apparent from the exemplary network 100 that an infrastructure modeling tool should preferably account for serial and parallel groups of components as well as the dependency between components in the network. Other aspects of the preferred availability analysis modeling tool will become apparent in light of the foregoing description of the preferred embodiment.

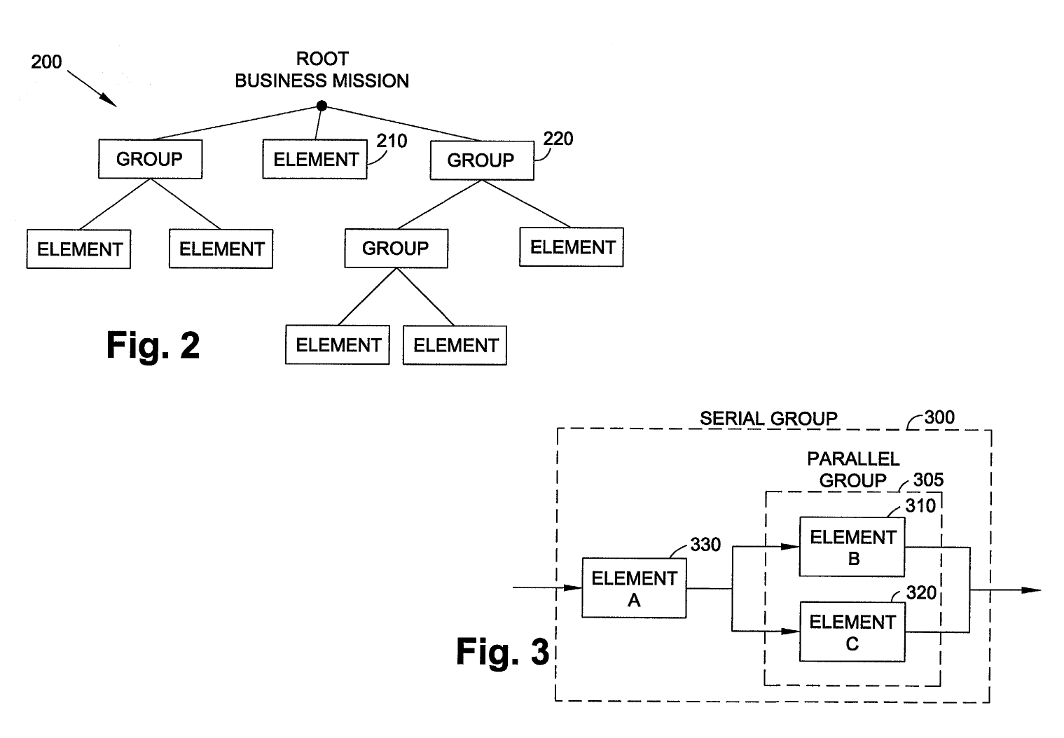

Referring now to FIG. 2, a representative hierarchical tree structure model of a business mission in accordance with the preferred embodiment is shown. The leaf components on the model 200 may be represented by either elements 210 or groups 220. Elements 210 are the lowest level component of a network model and represent a stand-alone device or software application. The elements 210, in turn, may be combined to form groups 220 of elements. It is also possible to combine groups and elements into even larger groups. Element groups may be designated as either parallel or serial. Two other types of groups (Countermeasure groups and Reference groups) are discussed below, but are also derived from serial or parallel groups. These groups 220 provide the modeler with the ability to impart a logical structure to the network model. There is conceptually no limit to the number of elements 210 and/or groups that can appear in a series or parallel element group 220, thus allowing for the creation of arbitrarily complex models that represent real-world configurations.

Elements 210 may be hardware or software elements. As will be discussed in more detail below, the preferred modeling algorithm simulates failures of both element types in generally the same fashion. However, the preferred embodiment also includes provisions for modifying the failure and repair times for software elements. As a preliminary example, a software recovery after failure may involve a system reboot or data restoration from backup media, whereas a hardware failure may require a wholesale replacement of the failed device. Parameters that define the extent to which a hardware or software failure affects the overall network are defined with a user interface as described below.

At the root of a network model, it is possible to assign a business mission to the elements. A business mission defines an expected workload that should be available over a period of one or more weeks. The business mission also defines the cost incurred should this workload not be available. Workloads are assigned in a cascading fashion such that the costs incurred at the top level of a model are the sum of all the costs incurred by sub-elements. The preferred availability analysis tool uses a Monte Carlo algorithm as a basis for establishing when failures occur and for determining how long it may take to recover from such a failure. When a failure occurs, the model attempts to repair the failure and recover the business mission. The model looks to repair and recovery factors such as service coverage, repair times, and the time at which a failure occurs. Thus, just like real-world failures, the preferred embodiment may treat a failure that occurs on a Monday morning different than it would a failure that occurs on a Friday afternoon.

Users of the preferred availability analysis tool can configure the model to apply various types of countermeasures by way of hierarchical definition of the components. An example of a simple countermeasure is a fully redundant parallel group where only one element is needed to run the group, but two or more elements are included in parallel as a safety backup. Other countermeasures such as shifting workload to other elements or inserting a less efficient element until the original element can be repaired or replaced may be incorporated. In any event, when a simulated failure occurs, countermeasure benefits are applied and an overall picture of system downtime and cost are determined. The preferred embodiment rolls up any elemental or group failures to the top level of the tree to compare the losses with the overall business mission and establishes costs for these failures. These failures are expressed in lost workload “Units” and represent the basis of establishing the business effect of lost availability. The preferred availability analysis tool considers the tradeoffs involved in incorporating countermeasure benefits and generates tailor made reports indicating results such as initial system costs, system availability, total downtime in hours, dollar costs of downtime, and element failure counts.

FIG. 3 shows an example of a simple model with a serial 300 and a parallel 305 group. Parallel group 305 includes two elements: element B 310 and element C 320 while serial group 300 includes element A 330 and parallel group 305. This simple model may represent a multi-CPU computer system where elements B 310 and C 320 represent processors while element A 330 represents a shared memory. In general, all elements in a serial group are necessary for the group to work. By comparison, elements in a parallel group share a workload. As long as a number of elements in a parallel group remain functional, the parallel group will still operate (perhaps at a reduced capacity). In this example shown in FIG. 3, if either element A 330 or the parallel group 305 (as a whole) fail, then serial group 300 also fails. However, if only element B 310 or element C 320 fail, the parallel group 305 and serial group 300 will continue to operate. In this latter case, the operating capacity for these groups 305, 300 may be limited if elements B & C are not fully redundant.

Serial groups 300 and parallel groups 305 are preferably assigned a number of parameters, including an impact delay time, failure propagation, and additional recovery time. Impact delay defines a delay time that elapses before the rest of the serial group is informed that a failure occurs in the element. The failure propagation parameter determines whether any adjacent elements within the group will also be forced to fail. Lastly, the additional recovery time may be added to the recovery time necessary for sub-elements and may be divided into fixed and variable components. In addition to the above parameters, parallel groups 305 are also assigned a minimum and maximum workload that are used as thresholds values for the work produced by the entire group. If the workload of the combined elements in a parallel group equals or falls below the minimum workload value, the group fails. Alternatively, the group may fail if the workload of the combined elements in the group falls below the minimum workload value. These workload values are explored in more detail below.

The behavior of the parallel group 305 shown in FIG. 3 may also be represented by a countermeasure group. A countermeasure group includes at least two elements: a main element and a counter element. In FIG. 3, element B 310 may be the main element and element C 320 may be the counter element. Under normal conditions, the main element carries the workload. However, when a failure occurs in the main element, the main element is replaced by the counter element until the main element is repaired and returned to normal operation. A countermeasure element is preferably assigned a number of parameters, including the time required to invoke and remove the countermeasure, countermeasure performance relative to the main element, and availability of the countermeasure (i.e., probability that the countermeasure is not already used elsewhere or that it may not work at all). The countermeasure group may also include an additional recovery parameter that adds time to the overall recovery of the group in the event the countermeasure fails.

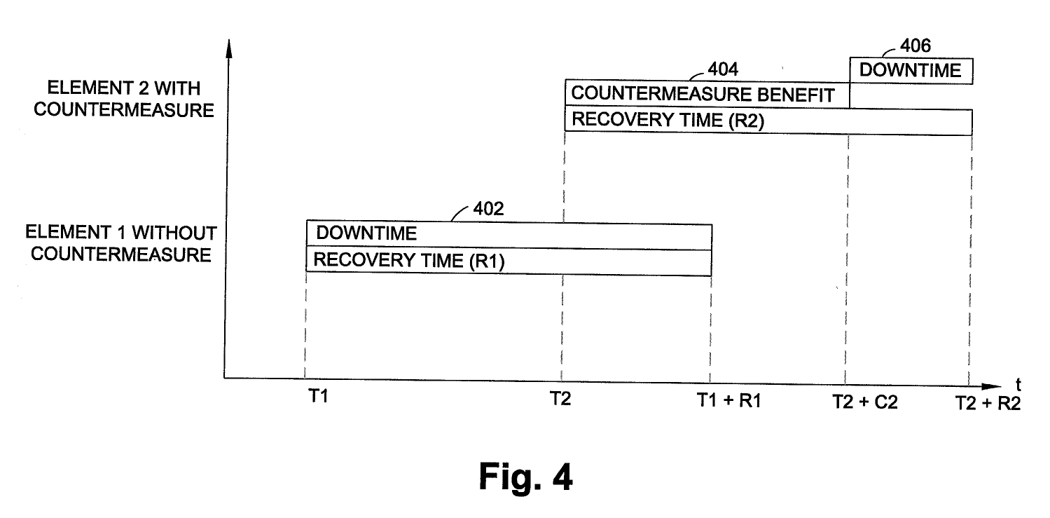

Referring now to FIG. 4, two representative timelines depicting the failure, recovery, and downtime effects of a component failure within the preferred embodiment are shown. In the first case, element 1 is modeled without a countermeasure. Consequently, when the element fails at time T1 (and assuming there are no redundant elements in the model), a failure occurs and a repair and recovery cycle begins. The time required to recover from this failure is represented by recovery time R1 such that at time T1+R1, the element will be fully operational again. In the meantime, the failure produces a concurrent downtime 402 that has an associated cost as defined by the business mission. In this particular case, the downtime 402 is equal to recovery time R1.

In the second case shown in FIG. 4, element 2 is modeled with a countermeasure. At the moment element 2 fails T2, a countermeasure element is deployed and a countermeasure benefit 404 is seen. In general, if the countermeasure element remains operational until the main element is repaired or recovered, then losses will be minimized or altogether eliminated. However, as is the case in FIG. 4, a countermeasure failure will result in a downtime 406 from the point the countermeasure fails T2+C2 until the main element or the countermeasure element is repaired or recovered T2+R2. As FIG. 4 shows, the downtime 406 caused by the failure of element 2 is significantly smaller than the downtime 402 caused by the failure of element 1. Accordingly, downtime costs associated with the failure of element 2 will also be smaller, but these costs must be weighed against the cost of implementing the countermeasure in the first place. The reports generated by the preferred embodiment advantageously allow customers to analyze these costs against one another.

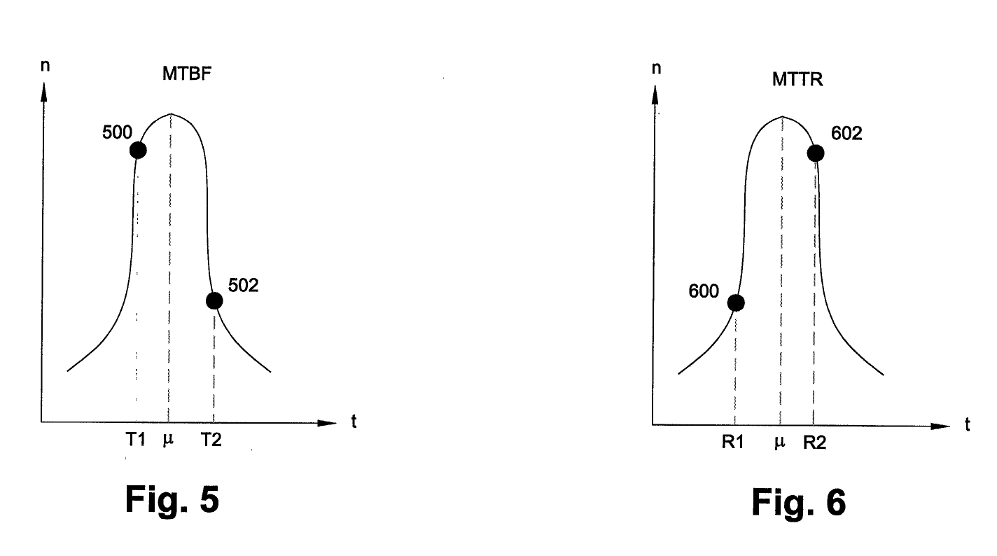

Referring now to FIGS. 5 and 6, example distributions of MTBF and MTTR used to assign failure and recovery points in the preferred embodiment are shown. As discussed above, a Monte Carlo algorithm is used as a basis for establishing when failures occur and for determining how long it may take to recover from such a failure. The algorithm preferably implements a pseudo-random number generator to generate failure times and repair or recovery times for use in the availability analysis software. Each element (including countermeasure elements) in the model has an associated mean time between failure (MTBF) number and a mean time to repair (MTTR) number, each expressed in hours. The model assumes that the MTBF and MTTR values are normally distributed, but the functional definition or shape of these distributions may be varied to match real world element behavior.

For each element in a model, the algorithm preferably simulates failures by assigning future failure points and repair times for each failure. Each failure has a corresponding repair and recovery phase. In FIG. 5, failure points 500 and 502 are shown at times T1 and T2. FIG. 6 shows associated recovery times 600, 602 at times R1 and R2. The failure points are used to initiate failures at discrete points in time. Then, for each simulated failure, an associated repair time can be added to this point in time to determine the point at which the element and/or group is once again operational. In each case, the time values used in the simulation are obtained by selecting random points on the respective MTBF and MTTR curves. These values are then used by the preferred embodiment to create an event timeline similar to that shown in FIG. 4.

It is worth noting that the preferred embodiment is fully capable of independently simulating failures in a countermeasure element in the same manner as a main element. Thus, the countermeasure element will possess MTBF and MTTR values that are uniquely different than the main element the countermeasure supports. This characteristic of the preferred embodiment allows users to account for differences between the main element and the counter element. For example, a counter element may be a new device. In such a case, infant mortality trends may cause the MTBF value for the counter element to be smaller than the main element. Other differences may also exist.

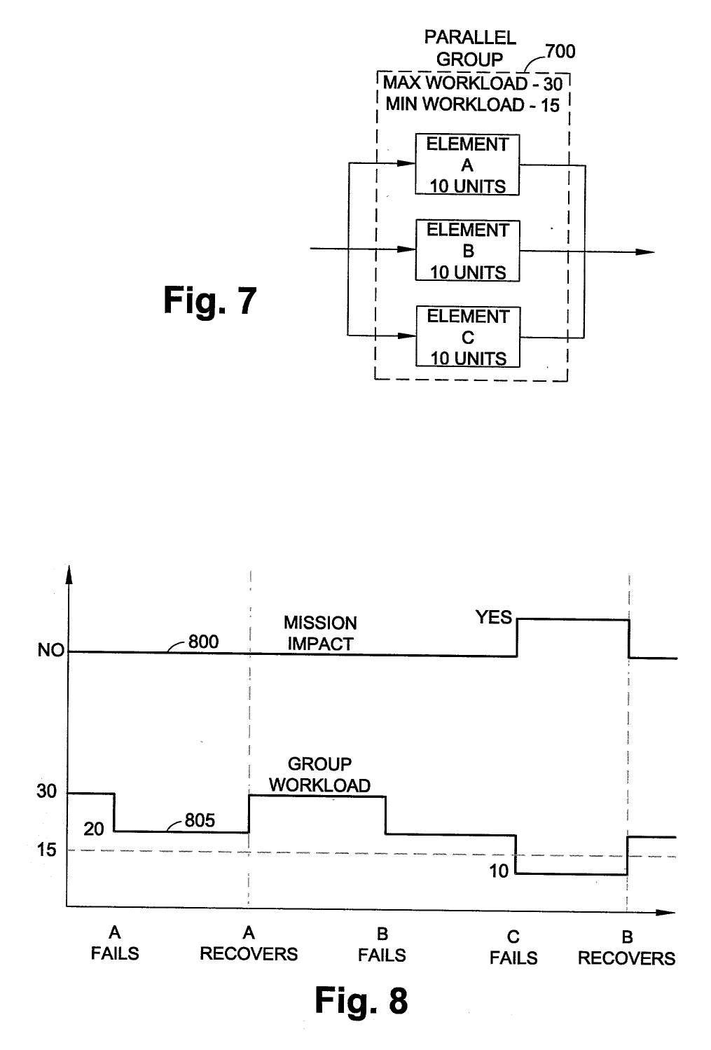

Referring now to FIG. 7, a representative implementation of a parallel group 700 of elements is shown. In accordance with the preferred embodiment, each of the elements A, B, and C are assigned a workload contribution to the entire group 700. For simplicity, each element A, B, C are assigned equal workload values of 10 units, although any combination of workload values are possible. Workload units represent the output of individual elements, and elements in a group preferably express workload in the same units. Actual workload of a group is not specified, but is instead calculated from the workloads of the member elements. Workload requirements may be specified for a group in terms of a minimum and/or maximum workload. Workload lost due to failures is the basis of calculating business impact and cost in the preferred embodiment.

In the parallel group shown in FIG. 7, the group 700 is assigned minimum and maximum workload requirements of 15 and 30 units, respectively. The impact of element failures on this example group 700 are shown on the timeline in FIG. 8, which includes two curves 800, 805. The upper curve 800 indicates whether the business mission is impacted at any point in time. The lower curve 805 in FIG. 8 represents actual group workload over time and may be referred to as a workload transition graph. With all three elements A, B, C in the group 700 operational, the group output is equal to the sum of the element outputs. In this case, the group output is 30 (10+10+10) workload units. If element A fails at some point in time, the group workload decreases by 10 units to 20 units until element A recovers or until some other element fails. At this point, however, the overall group workload has not fallen to or below the minimum workload requirement (15 Units). Hence, the upper curve 800 indicates that there is no mission impact. Once element A is repaired or recovered, the group workload returns to 30 units.

Referring still to FIG. 8, the same scenario just described repeats when element B fails. The overall group workload decreases to 20 units, but the overall business mission remains unimpacted. However, if element C fails before element B recovers, the overall group workload decreases yet again to 10 units (contributed by element A alone). At this point, the overall group workload falls below the minimum requirement of 15 units and the business mission is impacted as witnessed by the toggling of the mission impact curve 800. The parallel group 700 remains failed until one or both of the failed elements B,C are recovered. Finally, in the example shown in FIG. 8, element B recovers thereby increasing the overall group output to 20 work units, which returns the upper curve 800 back to the “No Impact” state.

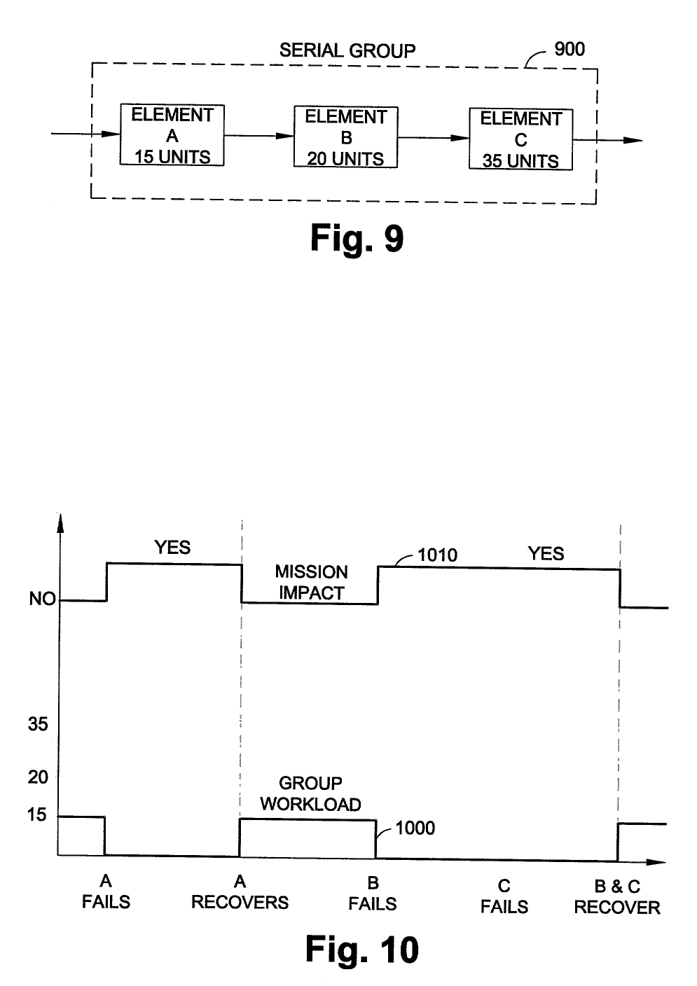

FIGS. 9 and 10 represent figures for a serial group analogous to those shown in FIGS. 7 and 8 for a parallel group. In FIG. 9, serial group 900 includes elements A,B,C capable of producing 15, 20, and 35 workload units, respectively. Unlike parallel groups, serial groups are not assigned maximum or minimum workload values since the actual workload produced by a serial group are determined by the element in that group with the smallest workload. For instance, in serial group 900, element A limits the overall group workload to 15 units. It is of no consequence that elements B and C are each capable of producing more than 15 units. Hence, the workload transition graph 1000 of FIG. 10, which represents the workload output from serial group 900, simply toggles between 15 units if all elements are working and 0 units if any elements in that group fail. As FIG. 10 shows, serial group 900 fails if any of elements A, B, or C fail. The upper curve 1010 in FIG. 10 reflects a “Yes” mission impact when element A fails and again when elements B and C fail. The only time the serial group is unimpacted is when all three elements A,B,C are operational.

Referring now to FIG. 11, it may be advantageous to provide additional functionality in controlling the consequences of a lost workload. A finer level granularity in the group workload level during the failure and recovery periods of a failed element may more accurately model a real-world failure. This extra control may is accomplished in the preferred embodiment using failure and recovery factors. The parallel group 1100 shown in FIG. 11 includes these failure workload factors and recovery workload factors assigned to the elements A, B, and C as well as a recovery factor assigned to the group 1100.

For elements A, B, C, a failure workload factor (FF) adjusts the workload calculated at the parent group relative to the actual workload produced by the element during the repair phase of the failure. A default value of 100% indicates the total loss of workload attributed to that element. Values smaller than 100% indicate that the group has some implicit capacity to support the lost workload associated with this element. In contrast, a value greater than 100% indicates that the group is impacted to a greater extent than just the loss of the element in question. It should be noted that a failure factor may be applied to elements in a serial group, but values greater than 100% will have no impact on the model since the workload for a group cannot be less than zero. In other words, a serial element can only be assigned FF values smaller than 100%.

A recovery workload factor (RF) is also assigned to elements A,B,C. The RF value adjusts the workload calculated at the parent group relative to the actual workload produced by the element during the recovery phase of the failure. In the context of this description of the preferred embodiment, recovery is distinguishable from repair by referring to the period of time following a successful repair, but before the element and/or group are operating as before the failure. A default RF value of 100% indicates the total loss of workload attributed to that element. Values less than 100% indicates that the element is capable of delivering some part of its workload during recovery. In contrast, a value greater than 100% indicates that the group is impacted to a greater extent than just the loss of the element in question. As with the failure factor, serial elements cannot be assigned an RF value larger than 100%.

Users may also wish to adjust the workload at the group level during a period of group level recovery. Hence, the preferred embodiment also includes a group recovery workload factor (GRF). This additional parameter is unrelated to any element that fails and is therefore attributable to the group. However, this parameter is similar to the RF value for elements. That is, the GRF value adjusts the workload calculated at the group relative to the actual workload produced by the group during the recovery phase after a recovery from failure in a member element. A GRF value of 100% indicates no loss of workload in the group associated with the recovery. In other words, once the element recovers, the entire group is capable of operating as it did pre-failure. A GRF value less than 100% indicates that the group is capable providing some part of its normal workload during recovery. In contrast, a GRF value greater than 100% indicates that the group is more efficient during recovery than in the steady state, perhaps reflecting the efficiency of the new element, refreshed system resources, or perhaps some attempt to recover lost workload. Group level recovery does not begin until all member elements of the group are up and will cease if a subsequent member element failure occurs during group recovery.

As a non-limiting example of the above features, the parallel group 1100 shown in FIG. 11 includes each of the above described parameters. Elements A,B,C are each assigned a workload of 20 units, an FF value of 120%, and an RF value of 80%. Similarly, the group is assigned a minimum workload of 40 units and a GRF value of 80%.

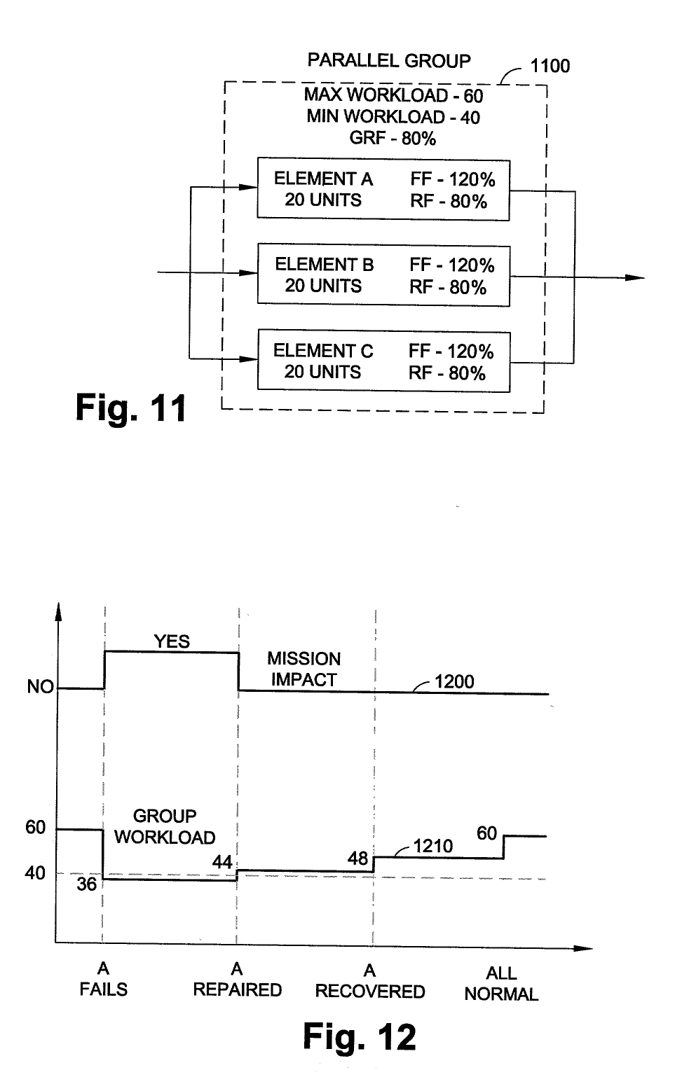

FIG. 12 includes a timeline similar to FIGS. 8 and 10 depicting an upper Mission Impact curve 1200 and a lower Group workload transition graph 1210. As before, the upper curve 1200 indicates a negative mission impact (YES) when the group workload falls below the minimum value entered by the user (in this case, 40 units). During steady state operations, each element A,B,C contributes 20 workload units to the group to yield a maximum group workload of 60 units. When a single element fails, the failure factor for that element must be considered. In this case, an FF value of 120% is assigned to each element. Consequently, the group workload is reduced from the maximum value of 60 units by an amount equal to 120% of the workload attributable to element A (i.e., 1.2*20=24 units). Thus, the group output is reduced from 60 units to 36 units when any single element fails. Since the group workload has fallen below the minimum required group workload of 40 units, the upper curve 1200 identifies this failure by toggling to indicate a mission impact.

After a failed element is repaired, that element enters a recovery phase during which the recovery factor must be considered. During this period, group workload is calculated in the same manner as with the failure factor. With an RF factor of 80%, the group workload is reduced from its maximum output of 60 units by 80% of 20 units or 16 units. Hence, during the element recovery phase, the group workload is 44 units, which represents an increase of 8 units over the element failure period. Since the group workload has risen above the minimum required group workload of 40 units, the upper curve 1200 toggles back to indicate no mission impact.

Once a failed element has recovered, the group enters a recovery phase during which the group recovery factor must be considered. During this period, group workload is calculated as a percentage of the normal operating workload. In this particular example, the GRF value of 80% means that the group output during the group recovery phase is 80% of the maximum output of 60 units or 48 units. Lastly, once the group recovery phase is complete, the group transitions back to steady state operation, or in this case, 60 workload units.

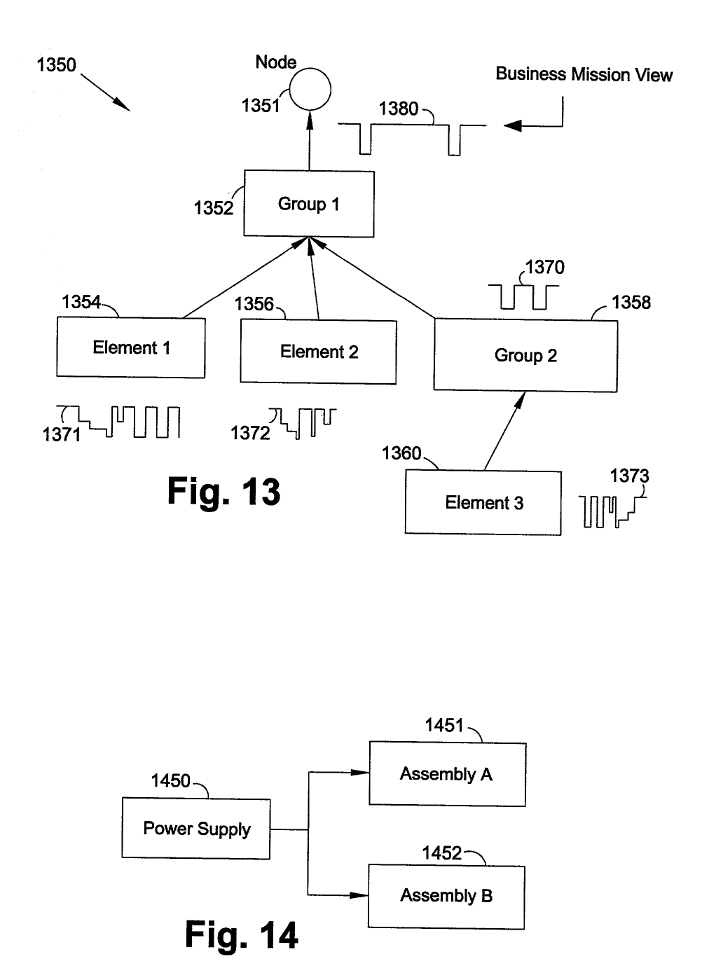

In each of the above workload calculations, the elements and/or groups are characterized by a workload transition graph 805, 1000, 1210 that show how workload for that individual model is expected to fluctuate over time. This fluctuation is the basis for calculating the cost of lost workload within the model. Referring now to FIG. 13, a simple model tree 1350 is shown that includes workload transition graphs for each element or group in the model. The model 1350 includes a first Group 1 1352 containing two Elements 1 1354, Element 2 1356, and a second Group 2 1358, which contains Element 3 1360. Each group and element provides a workload to the overall business mission as represented by the workload transition graphs 1370-1373 shown next to each group or element.

As with the example groups heretofore discussed, workload reductions in element models have varying impacts on the workload produced by a parent group. Thus, group level impact is determined by rolling up the workloads from each of the elements (and possibly groups) within a group model and calculating workload for that group. Accordingly, workloads are rolled up in a model tree 1350 to a common node 1351 and interpreted at this top level to provide the workload transition graph 1380 for the overall model. This logical representation is used to model components as they would be configured in a real world configuration. Note also that each element contributes a unique workload pattern to the overall model and that groups contribute unique patterns based on group attributes and patterns from group members.

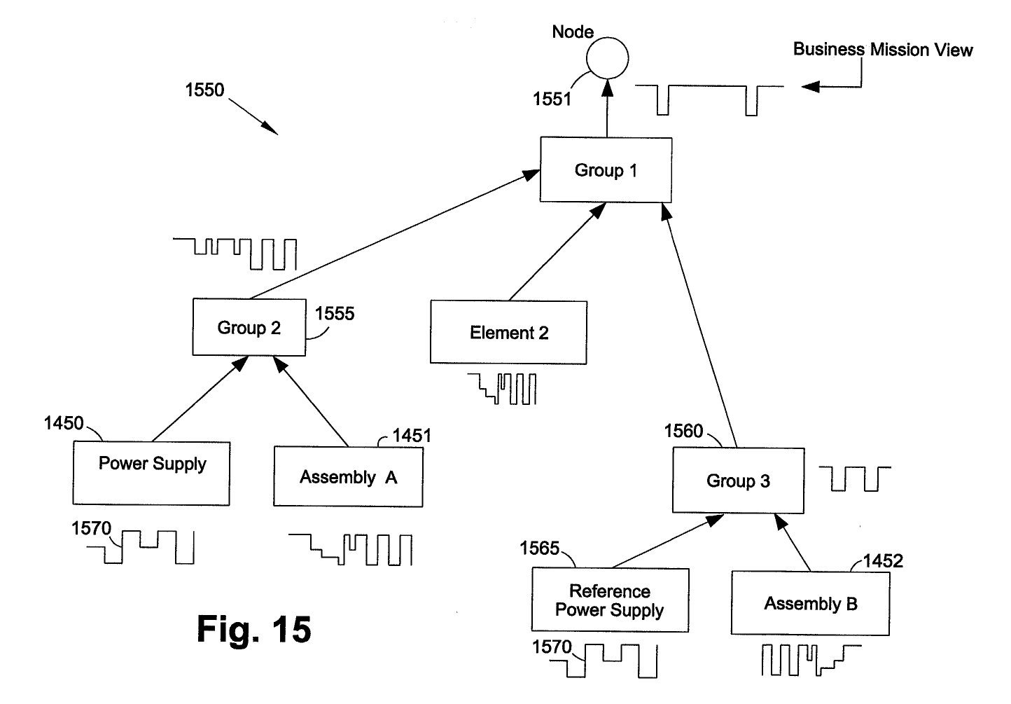

In the example model tree 1350 shown in FIG. 13, the workload transition graphs 1370-1373 are unique to each element or group model. This will generally be the case if each element or group represent unique components in an IT network. However, in real world configurations, it may be common to see elements or groups have a similar effect in more than one area of a model tree. One example is when a single component is shared between different portions of the model. This example is represented by the simple diagram shown in FIG. 14, which shows a single power supply 1450 providing power to two separate devices: Assembly A 1451 and Assembly B 1452. If the Power Supply 1450 fails, this will have an impact on Assembly A 1451 and Assembly B 1452 together. In an IT network, assemblies 1451, 1452 may belong to separate physical entities (as shown in FIG. 15) whose failures may impact the business mission in varying degrees. This variability can be built, using the preferred embodiment, into the logical structure of the model. In a case like this, it would be inappropriate to model two separate instances of power supply 1450 in a model tree because the simulation engine in the preferred embodiment would invariably (and incorrectly) generate two distinct failures.

A more accurate solution is to include a reference element as provided by the preferred embodiment. The model tree 1550 shown in FIG. 15 is built up using Assembly A 1451 and Assembly B 1452 in different positions of the tree to represent that failures in these assemblies 1451, 1452 will have a different impact on the overall business model 1551. Power supply unit 1450 is included in the model tree 1550 as a component of group 2 1555 to reflect the dependence of assembly A 1451 on the power supply 1450. However, the impact of a failure in power supply 1450 on group 3 1560 and on assembly B 1452 must also be considered.

In accordance with the preferred embodiment, this problem is solved by using reference elements and reference groups. A reference element is a pseudo element added into the model which uses the simulated failure characteristics of another element. In the present example, group 3 1560 includes a reference element 1565, which refers to the power supply unit 1450 in group 2 1555. This reference power supply element 1565 is not simulated, but instead uses the workload transition graph generated from the referenced element 1450 in Group 2 1555.

During failure simulation, the preferred embodiment calculates the workload transition graph 1570 for the power supply 1450 in Group 2 1555. This workload transition graph 1570 is also used for the reference power supply element 1565 in Group 3 1560. The advantage of this configuration is that the workload/time characteristics are interpreted for an element that resides in a different portion of the model tree. The preferred embodiment simulates the failure and recovery events only once for the power supply unit 1450, but duplicates these events in a different portion of the network to simulate a real world configuration.

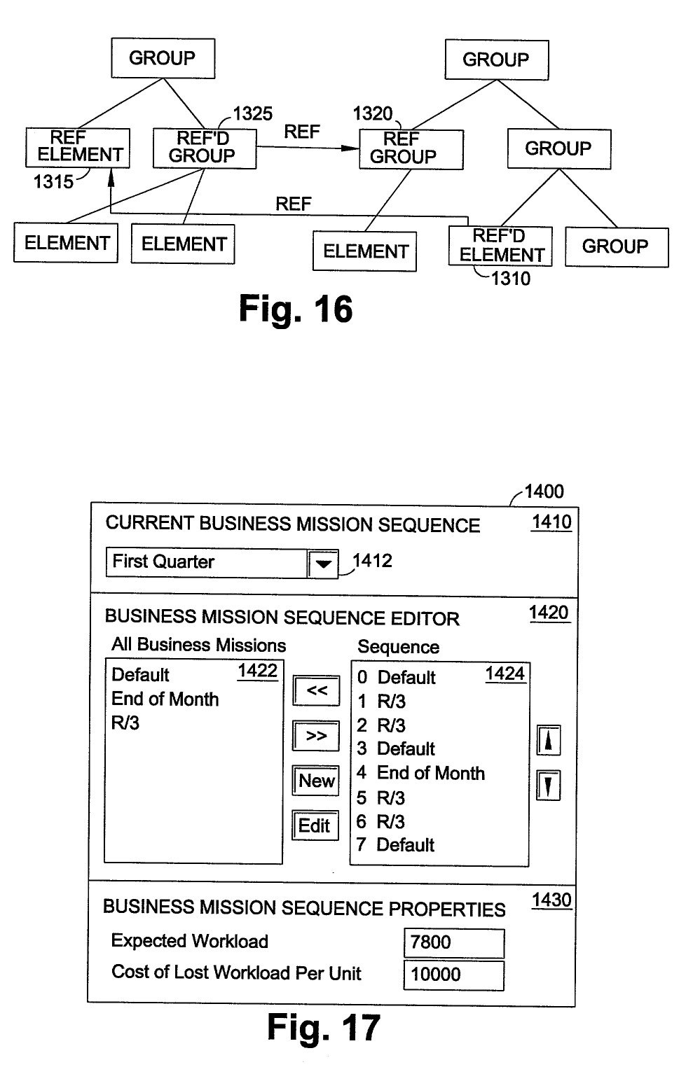

To build on the flexibility that a reference element provides, the preferred embodiment incorporates the use of reference groups that operate in the same fashion as element groups. That is, a reference group uses the workload transition graph from another group in a model tree. As a general example, the model tree 1300 in FIG. 16 includes one instance each of a reference element 1315 and a reference group 1320. Like reference elements, a reference group 1320 is not treated as an independent group, but instead assumes the characteristics of the referenced group 1325. In some instances, it may be desirable to apply different group workload recovery factors to the reference group 1320 to account for the placement of that group in a different portion of the model.

In the generic example shown in FIG. 16, element 1315 is a reference to element 1310. Stated another way, element 1315 is the reference element while element 1310 is the referenced element. Alternatively, referenced element 1310 may also be described as a master or parent element, while reference element 1315 may be characterized as a slave or child element. The same nomenclature is preferably used with reference groups as well.

As with the specific example shown in FIG. 15, failures in the referenced components (elements and/or groups) 1310, 1325 of FIG. 16 are relayed to the reference component 1315, 1320 for processing in the context of the reference component. Failures in the reference components 1315, 1320 are not independently simulated. In other words, unique failures and repair/recovery times are not directly generated for the reference components 1315, 1320, only for the referenced components 1310, 1325. This feature is useful for different business models that share a common component while preventing multiple representations of that shared component from being simulated independently.

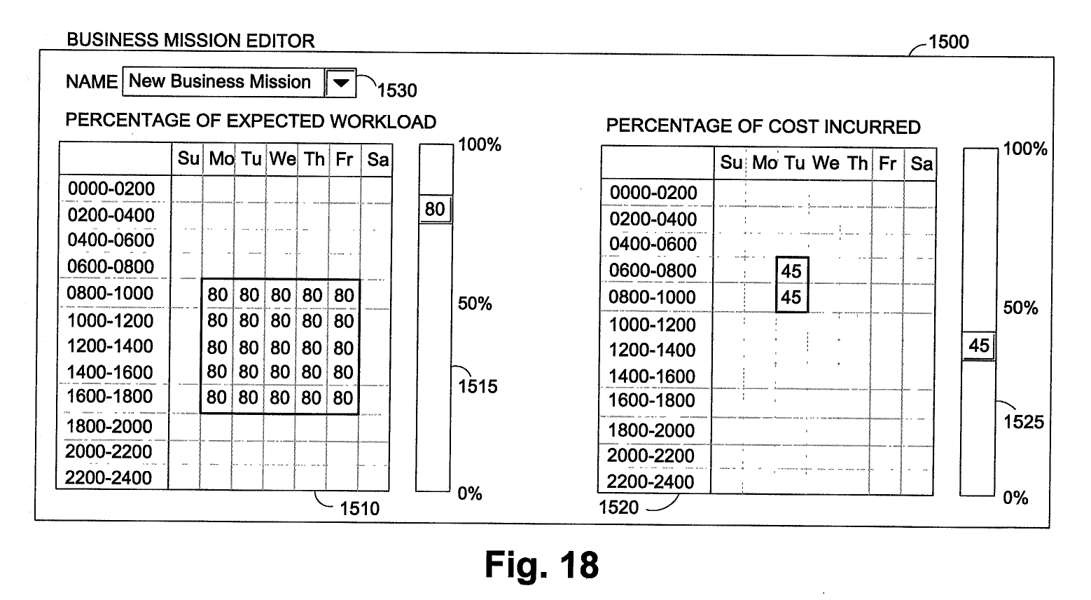

Referring now to FIG. 17, the preferred availability analysis software provides failure simulation and variable cost impact of downtime depending on when a failure occurs. Business missions are incorporated at the top level of any business model. The business mission interface shown in FIGS. 17 and 18 is the means by which a customer views any prospective IT deployment and how it supports their business. The preferred embodiment seeks to capture the fact that downtime can have a greater impact at certain times. For example, network uptime during financial reporting periods, end of month accounting periods, or quarterly production runs is more critical than others. The preferred embodiment provides analyses and availability estimation using the concepts of a variable business mission and a variable cost impact.

Business missions are preferably implemented as variable weekly periods. In the user interface window 1400 shown in FIG. 17, three different business mission functions are provided. At the top of FIG. 17 is a business mission sequence selector 1410. In the center is a business mission sequence editor 1420 and at the bottom of the interface window are the global business mission sequence properties 1430. The current business mission sequence 1410 is a user-selectable sequence that determines the order in which the weekly business missions are implemented. Sequence choices are made using a drop-down list 1412 that contains all predefined sequences. Each sequence is comprised of a configurable string of one or more weekly business missions. As an example, a first quarter sequence may include a sequence of 13 business missions, each business mission representing a week in the first quarter of a fiscal year. Since business mission sequences are user-defined, any combination of business missions may be created.

In the center of the user interface window is a business mission sequence editor 1420 that is used to create or edit a sequence of business missions. On the left side of the sequence editor 1420 is a list 1422 of all available business missions. On the right side of the sequence editor 1420 is a business mission list 1424 representing the current sequence. Business missions may be added or removed from this sequence list by selecting the right (>>) or left (<<) chevron buttons at the center of the sequence editor 1420. In addition, the order in which the business missions appear may be changed by highlighting a business mission in the list 1424 and moving that business mission up or down using the up or down arrows at the right side of the sequence editor 1420. Lastly, business missions may be created or edited by selecting the “New” or “Edit” buttons in the center of the sequence editor, which in turn will pull up the business mission editor 1500 shown in FIG. 18. The business mission editor is described in further detail below.

The last feature shown in the user interface 1400 of FIG. 17 is the global business mission sequence properties 1430. Two specific variables are assignable in this window that allow the software to determine system impact and downtime costs when a failure occurs in a given time frame. The first variable is the expected system workload and defines the maximum expected load expressed in workload units. The expected workloads for all time slots in the business model editor 1500 shown in FIG. 18 are then expressed as a percentage of this number. The second variable is the cost of lost workload per unit value. This number places a dollar figure on each workload unit lost during downtime of all or a portion of the network. Thus, once the availability analysis tool rolls up all lost workload units that result from a failure, this value allows the software to generate a dollar figure for cost of lost workload that IT customers can understand.

The individual business missions 1422 listed on the left side of the user interface 1400 in FIG. 17 includes a default and all user-created business missions. The example shown in FIG. 17 includes an “End of Month” business mission and an example “R/3” business mission. The End of Month mission may be characterized by a heavier workload and a greater associated financial impact from any downtime that may occur during the week. By comparison, the R/3 business mission may simply represent a standard operating mode where the client server network is running SAP's R/3 integrated software solution. As discussed above, users may edit existing business missions or create new business missions using the business mission editor 1500 shown in FIG. 18.

Referring now to FIG. 18, the business mission editor 1500 includes two weekly calendars, with each day of the week divided into two-hour slots. The preferred interface shown in FIG. 18 shows an expected workload calendar 1510 and a cost incurred calendar 1520. When failures occur in the simulation model, the lost workload is mapped onto these calendars (based on when the simulated failure occurs and remedial service response) to determine whether the lost workload affects the expected availability as well as the cost of lost workload. The two-hour slots in each calendar are independently selectable or can be selected as part of a group of two-hour slots. Once selected, the value assigned to the two-hour slots can be changed using the sliding scale 1515, 1525 on the right side of the calendar. In the expected workload calendar 1510 of the example editor 1500 shown in FIG. 18, the time slots corresponding to 8:00 AM to 6:00 PM Monday through Friday have been highlighted and the sliding scale 1515 has been set to 80%. This setting means that the business mission output for these hours of these days is expected to be 80% of the expected workload value entered into the user interface 1400 shown in FIG. 17.

Similarly, in the cost incurred calendar 1520, the time slots corresponding to 6:00 AM to 10:00 AM Tuesday have been highlighted and the sliding scale 1525 has been set to 45%. This setting means that the cost impact for failures occurring during these hours is expected to be 45% of the value entered into the Cost of Lost Workload Per Unit value entered into the user interface 1400 shown in FIG. 17. Once all time slots are adjusted to the user's requirements, the business mission is assigned an identifying name 1530 and saved so that the new or edited business mission is available in the business mission list 1422 in user interface 1400. The flexibility offered by the business mission editor 1500 allows users to generate tailored failure simulations and results that coincide with real-world requirements and experiences.

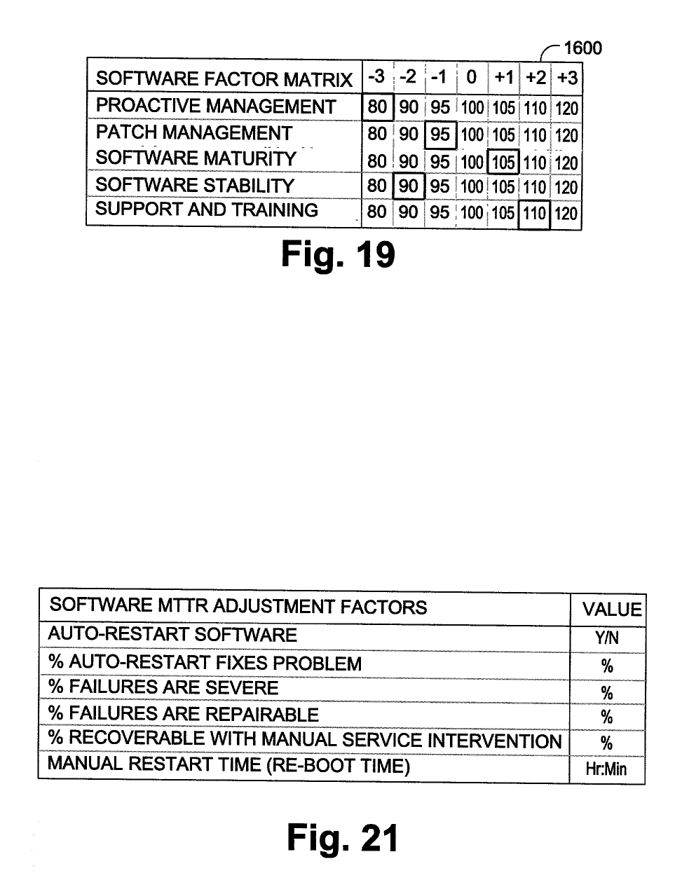

Referring now to FIG. 19, the preferred availability analysis tool simulates failures in software elements slightly different than it does hardware failures. Each software element is characterized by mean time between crashes (NTBC) and mean time to repair (MTTR) values analogous to the MTBF and MTTR values for hardware elements discussed above. These numbers are expressed in hours. However, prior to failure simulation, the MTBC value is adjusted up or down based on a number of software factors. These factors are shown in the software factor matrix 1600 in FIG. 19. Software reliability and stability depends, in part, on the factors shown in the software matrix 1600. For each factor, a positive or negative adjustment factor can be selected. Adjusting a particular software element factor up or down results in an associated adjustment to the value of MTBC. In general, good software management practices, including maintaining software updates and providing adequate training improve software reliability. These factors can be appropriately considered using the software matrix map. The individual factors included in the preferred software matrix map 1600 include: proactive management, patch management, software maturity, software stability, and support and training. Users may adjust the individual factors by sliding a selection box left (negative) or right (positive) using the interface shown in FIG. 19. It should be noted that while only 7 levels of adjustment (from −3 to +3) are shown in FIG. 19, alternative embodiments may optionally incorporate finer levels of adjustment.

The proactive management factor is based on how effectively a user manages the software. Items that may be considered are the maintenance of effective documentation and documentation change control procedures and whether there is a system available to diagnose and provide early warning of pending failures or incidents. The patch management factor considers whether software patches are planned and applied in accordance with industry best practices. The software environment factor is based on whether the software element operates in a stable or dynamic environment. For instance, a test system may experience more frequent outages than a production or design system. The software stability factor depends on the rate of change of software elements within the model. Generally, frequent version changes or regular use of alpha or beta software releases increases failure rates. Lastly, the support and training factor depends on whether there are trained personnel or support staff on site to handle software management, debugging, or installation. Each of these factors can have a positive or negative impact on the MTBC value and can be adjusted accordingly.

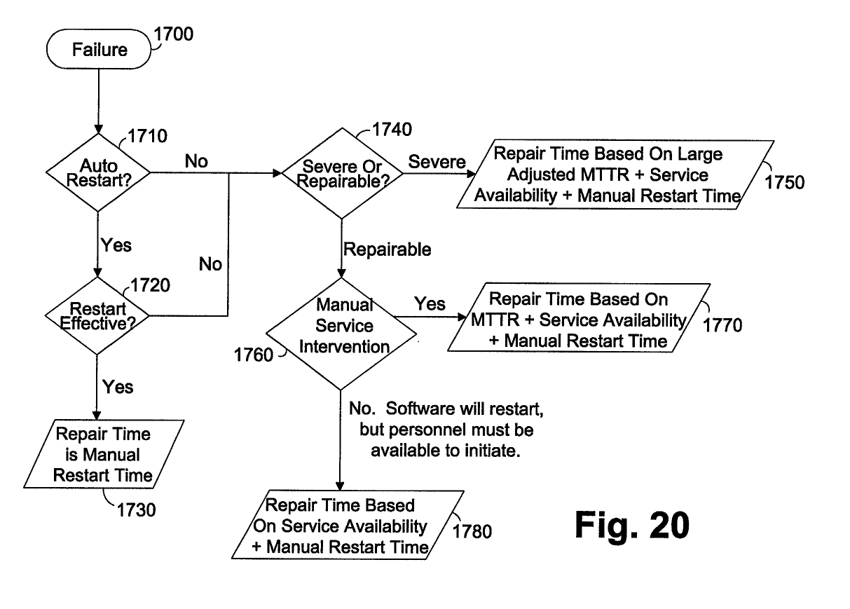

Referring now to FIG. 20, the MTTR value for software elements can also be adjusted similar to the MTBC adjustments. Some software failures are induced by hardware failures and should therefore not be considered “real” failures. Similarly, some software failures require only a restart to recover while others require diagnostics and special activities to restore the element to the business mission. The decision tree shown in FIG. 20 represents the method used by the preferred embodiment to adjust the MTTR. Implementation of this decision tree depends on a number of factors that are input from a user interface. These factors are shown in tabular form in FIG. 21.

The first factor shown in FIG. 21 establishes whether an auto-restart function is built into the system. If enabled, a software application that stops responding to an operating system may be killed and restarted by the operating system. Even when this feature is enabled, it may still be the case that an automatic restart does not repair the failure. The second factor establishes the percentage of software failures that are repairable with the auto-restart function. The third factor establishes the percentage of failures that are classified as severe or failures that can be repaired with some level of manual service intervention or failures that require a reboot but must be initiated by a human. Severe failures result in large periods of downtime and perhaps require a complete reinstall of the software and require extensive external help to repair. For severe failures, the preferred software tool looks to service coverage factors, quality of service, re-boot time and a larger MTTR calculated via a user defined scalar value referred to as a Catastrophe factor to establish how long a repair will take. Those failures that are not severe are classified as repairable. Repairable failures fall into two categories: Those that require manual service assistance to effect the repair and those that simply require a reboot that must be initiated by a human. Thus, the sum of the severe and repairable percentage values should equal 100%. Another factor used to adjust the MTTR value for software elements is the percentage of software failures that recover with a manual service intervention or a simple computer reboot. Lastly, users may enter information on the amount of time required to wait for the restart of the failed software element. This is commonly known as the reboot time.

The above factors are used in conjunction with the decision tree shown in FIG. 20 to adjust the default MTTR value generated by the preferred embodiment. After a software failure 1700, the preferred embodiment first checks to see whether the auto-restart function is enabled 1710. If enabled, the software then checks to see the percentage of time the auto-restart function works 1720. If the auto restart function works, the returned value is the “reboot time” 1730 since recovery time will be minimal. On the other hand, if either the auto restart function is disabled or the auto-restart fails, software analyzes the extent of manual interaction needed to repair and recover the failed software element.

If all auto-restart functions fail, the software classifies the failure as severe or repairable 1740 based on the user generated factors above. If the failure is classified as severe, the MTTR is increased by a large mean time to recover (MTTRec) value 1750 that is preferably generated in a manner similar to the MTTR value and that is based on historical repair information and availability of service coverage. If, on the other hand, the failure is classified as repairable, the software determines the percentage of failures that are repairable with manual service intervention 1760. For those failures repairable with manual service intervention, the simulated MTTR value is adjusted upward by adding the user-entered manual restart time and the time calculated based on remedial service coverage (Service Factors) 1770. For failures that are not repairable with manual intervention, the MTTR value returned is the user-entered manual restart time plus the time calculated based on remedial service coverage (Service Factors) 1780. For each of the above scenarios, the preferred embodiment uses the adjusted MTBC and MTTR values and establishes a failure/repair/recovery timeline as with hardware element failures.

The above discussion is meant to be illustrative of the principles and various embodiments of the present invention. Numerous variations and modifications will become apparent to those skilled in the art once the above disclosure is fully appreciated. For example, adjustments similar to those applied to the software failure and repair times may also be applied to hardware elements. For instance, hardware elements that exist in harsh testing environments may experience more frequent failures. Similarly, business missions based on time periods longer or shorter than one week and including time slots longer or shorter than two hours may easily be incorporated. It is intended that the following claims be interpreted to embrace all such variations and modifications.

What is claimed is:

1. A method of estimating the cost of downtime in an information technology network comprising:
creating a computer model of individual components in the information technology network;
assigning a numerical workload to each component in the information technology network;
simulating component failures in the computer model;
calculating the amount of workload that is lost from the simulated component failures; and
assigning a cost per unit workload lost during a component failure;
wherein the estimated cost of downtime caused by component failures is determined by multiplying the amount of workload that is lost from the simulated component failures by the cost per unit workload.

2. The method of claim 1 wherein step of creating a computer model of individual components in the information technology network comprises:
identifying functionally separable components in the information technology network;
creating an element model for each components in the information technology network;
combining element models into logical group models to simulate real-world configurations; and
creating a hierarchical model tree of element and group models to simulate the information technology network.
wherein the element models are assigned a numerical workload and are combinable within the group models in a serial or parallel manner.

3. The method of claim 2 wherein when element models are combined in a serial manner in a group model, the failure of any element model in the group model causes the group model to fail.

4. The method of claim 2 wherein when element models are combined in a parallel manner in a group model, the sum of the workloads assigned to the individual element models determine the overall workload for the group model.

5. The method of claim 4 wherein the group models are assigned a minimum workload and wherein if failures of element models within the group cause the total workload for the group to fall equal to or below the minimum workload, the group model fails.

6. An network availability analysis software tool comprising:
a network modeling function comprising element and group models to represent network components;
a business mission editor for creating variable business missions, each mission representing a grouping of adjacent time slots that are each assigned an expected network workload and network downtime cost;
a user interface for creating a sequence of the variable business missions; and
a failure simulator that generates failure points and repair times for the models based on historical reliability of the network components;
wherein the failure points and repair times are mapped against the sequence of business missions to determine which variable business mission is impacted by the failure point.

7. The network availability analysis software tool of claim 6 wherein the failure simulator further generates failure points and repair times for the models based on availability of remedial service coverage to effect repairs when failures occur; and
wherein the failure points and repair times are mapped against a calendar of available remedial service coverage to determine how repair time is impacted by the failure point.

8. The network availability analysis software tool of claim 7 wherein the failure points and repair times are compared to the expected network workload and network downtime cost assigned to the time slot during which the failure occurs to calculate a downtime cost associated with each failure.

9. The network availability analysis software tool of claim 8 wherein the user interface allows a software user to enter a maximum expected network workload and network downtime cost.

10. The network availability analysis software tool of claim 9 wherein the business mission editor allows a software user to enter an expected network workload and a network downtime cost to each time slot as a percentage of the maximum expected workload and maximum network downtime cost.

11. The network availability analysis software tool of claim 10 wherein the variable business missions are one week long and the time slots are two hours long.

12. A method of cost estimating software failures in a network simulation tool comprising:
modeling a software application as a software element in a network model, said software element producing a workload when operating but which produces no workload when failed;
creating a business mission comprising adjacent time slots, each time slot characterized by an expected network workload and network downtime cost;
assigning a future failure time to the element based on a mean time between crash (MTBC) value for the software application;
assigning a repair time to the element based on a mean time to repair (MTTR) value for the software application; and
estimating the cost of the software failure by
i. placing the future failure time in the appropriate time slot in the business mission and if the workload lost by the failure of the software element impacts the expected network workload for that time slot,
ii. calculating the cost of the software failure from the network downtime cost for that time slot and the expected repair time for the software element.

13. The method of claim 12 further comprising adjusting the future failure time based on user-definable software stability factors.

14. The method of claim 13 wherein the software stability factors comprise:
proactive management factor;
a patch management factor;
a software maturity factor;
a software stability factor; and
a support training factor;
wherein each of the software stability factors are adjustable to delay a future failure time if existing business practices represented by the factors lead to a more stable software application, and
wherein each of the software stability factors are adjustable to accelerate a future failure time if existing business practices represented by the factors lead to a less stable software application.

15. The method of claim 12 further comprising adjusting the expected repair time based on user-definable repair adjustment factors.

16. The method of claim 15 wherein the repair adjustment factors comprise:
whether a software auto-restart function is enabled;
the percentage of time a restart initiated by an enabled auto restart function fixes a software failure;
the percentage of time software failures are categorized as severe;
the percentage of time software failures are categorized as repairable;
the percentage of time a manual service intervention fixes a software failure; and
an estimated manual software restart time;
wherein if the software auto-restart function is enabled and a simulated failure is repaired by a restart initiated by the enabled auto restart function, the expected repair time is defined as the manual software restart time.

17. The method of claim 16 wherein if a simulated failure is not repaired by a restart initiated by the enabled auto restart function, the expected repair time is increased to account for a more extensive repair effort.

18. The method of claim 17 wherein if the simulated failure is categorized as severe, the expected repair time is increased by adding an extensive repair and recovery time.

19. The method of claim 18 wherein if the simulated failure is categorized as repairable by a manual service intervention, the expected repair time is increased by adding the estimated manual restart time, the time calculated based on availability of remedial service coverage and the element MTTR.

20. The method of claim 19 wherein if the simulated failure is categorized as repairable, but not by a manual service intervention, the expected repair time is increased by adding the estimated manual restart time and further adding an estimated repair time based on available remedial service coverage.

21. An network availability analysis software tool comprising:
a network modeling function that uses element and group model members to create a simulated network, said element model members representing components in the simulated network and said group model members comprising at least two element model members;
a failure simulator that generates failure points and repair times for the element and group model members based on historical reliability of the network components and availability of remedial service coverage,
wherein the network modeling function establishes correlated references between a slave reference model member and a master referenced model member that permit sharing of the same model member in different portions of the simulated network and wherein the failure simulator generates failure points and repair times for the master referenced model member, but not for the slave reference model member.

22. The network availability analysis software tool of claim 21 wherein failure points and repair times generated for the master referenced model member are imparted onto the slave reference model member.

23. The network availability analysis software tool of claim 22 wherein the failure simulator further generates recovery times for the model members based on an expected time needed to return to pre-failure operating capacity following a failure and repair.

24. The network availability analysis software tool of claim 23 wherein recovery times for correlated slave reference and master referenced group model members are independently simulated.

25. A method of estimating the cost of downtime in an information technology network comprising:
creating a computer element model of individual software and hardware components in the information technology network;
combining element models into logical group models to simulate real-world configurations;
creating a model tree of element and group models to simulate the information technology network.
assigning an element workload to each element in the information technology network, said element workloads being summable to determine group and model tree workloads;
simulating element failures in the model tree that reduce workload generated by a failed element;
omitting from the total group or model tree workloads the workload loss that is contributed by the simulated element failures; and
assigning a cost per unit workload lost at the model tree;
wherein the estimated cost of downtime in the model tree caused by element failures is determined by multiplying the amount of workload that is lost in the model tree times the cost per unit workload.

26. The method of claim 25 wherein the step of simulating element failures in the model tree further comprises:
generating failure points, repair times, and recovery times for the element models based on historical trends for the network components represented by the element models and availability of remedial service coverage;
applying user-definable workload factors to increase or decrease the workload loss encountered by the group or model tree during a simulated element failure.

27. The method of claim 26 further comprising:
defining an element failure workload factor that increases or decreases the workload loss encountered by the group or model tree during the time a simulated element fails, but before the element is repaired.

28. The method of claim 27 further comprising:
defining an element recovery workload factor that increases or decreases the workload loss encountered by the group or model tree during the time after which a simulated element failure is repaired, but before the element has recovered.

29. The method of claim 28 further comprising:
defining a group recovery workload factor that increases or decreases the workload loss encountered by the group or model tree during the time after which a simulated element has recovered from a failure, but before the group in which the failed element resides has recovered.

30. A method of estimating downtime in an information technology network comprising:
creating a computer element model of individual software and hardware components in the information technology network;
combining element models into logical group models to simulate real-world configurations;
creating a model tree of element and group models to simulate the information technology network.
assigning an element workload to each element in the information technology network, said element workloads being summable to determine group and model tree workloads;
simulating element failures in the model tree that reduce workload produced by a failed element;
simulating group failures if element failures within a group model cause the group workload to fall below a predetermined group workload minimum;
omitting from the model tree workload the workload loss that is contributed by the simulated element and group failures; and
wherein the estimated downtime in the information technology network is determined by comparing the simulated model tree workload to an expected network workload.

31. The method of claim 30 wherein the expected network workload is a user-definable business mission comprising adjacent time slots, each time slot characterized by an expected network workload.

32. The method of claim 31 wherein the estimated downtime in the information technology network accrues whenever the simulated model tree workload falls to zero.

33. The method of claim 31 wherein the estimated downtime in the information technology network accrues whenever the simulated model tree workload falls below the expected network workload.
